(19) United States
(12) Patent Application Publication
(10) Pub. No.: US 2006/0034366 A1
(43) Pub. Date: Feb. 16, 2006

(54) Low-IF multiple mode digital receiver front end and corresponding method

(75) Inventors: Michael Schmidt, Dresden (DE); Eric Sachse, Dresden (DE); Menno Mennenga, Dresden (DE)

Correspondence Address: MEYERTONS, HOOD, KIVLIN, KOWERT & GOETZEL (AMD), P.O. BOX 398, AUSTIN, TX, 78767-0398, US

(73) Assignee: Advanced Micro Devices, Inc.

(21) Appl. No.: 11/181,236

(22) Filed: Jul. 14, 2005

(30) Foreign Application Priority Data
Jul. 30, 2004 (DE) 10 2004 036 994.1

(51) Int. Cl. H03K 9/04

(52) U.S. Cl. 375/239

(57) ABSTRACT

A data communications technique is provided that may be used in WLAN (Wireless Local Area Network) receivers. Data signals modulated in accordance with one of at least two different modulation schemes are received. The front end of the device has an analog and a digital part, and the digital front end includes a first and a second signal processing branch for processing received data signals modulated in accordance with different modulation schemes. The first and second processing branches have low-IF (Intermediate Frequency) topologies. There is further provided a corresponding integrated circuit chip and a method of processing received data signals.

### BACKGROUND OF THE INVENTION

1. Field of the Invention

The invention generally relates to data communications devices such as WLAN (Wireless Local Area Network) receivers and corresponding methods, and particularly to front end techniques in such devices.

2. Description of the Related Art

A wireless local area network is a flexible data communications system implemented as an extension to or as an alternative for, a wired LAN. Using radio frequency or infrared technology, WLAN systems transmit and receive data over the air, minimizing the need for wired connections. Thus, WLAN systems combine data connectivity with user mobility.

Today, most WLAN systems use spread spectrum technology, a wide-band radio frequency technique developed for use in reliable and secure communication systems. The spread spectrum technology is designed to trade-off bandwidth efficiency for reliability, integrity and security. Two types of spread spectrum radio systems are frequently used: frequency hopping and direct sequence systems.

The standard defining and governing wireless local area networks that operate in the 2.4 GHz spectrum, is the IEEE 802.11 standard. To allow higher data rate transmissions, the standard was extended to 802.11b that allows data rates of 5.5 and 11 Mbps in the 2.4 GHz spectrum. Further extensions exist.

Examples of these extensions are the IEEE 802.11a, 802.11b and 802.11g standards. The 802.11a specification applies to wireless ATM (Asynchronous Transfer Mode) systems and is primarily used in access hubs. 802.11a operates at radio frequencies between 5 GHz and 6 GHz. It uses a modulation scheme known as Orthogonal Frequency Division Multiplexing (OFDM) that makes possible data speeds as high as 54 Mbps, but most commonly, communications take place at 6 Mbps, 12 Mbps, or 24 Mbps. The 802.11b standard uses a modulation method known as Complementary Code Keying (CCK) which allows high data rates and is less susceptible to multi-path propagation interference. The 802.11g standard can use data rates of up to 54 Mbps in the 2.4 GHz frequency band using OFDM. Since both 802.11g and 802.11b operate in the 2.4 GHz frequency band, they are completely inter-operable. The 802.11g standard defines CCK-OFDM as optional transmit mode that combines the access modes of 802.11a and 802.11b, and which can support transmission rates of up to 22 Mbps.

WLAN receivers and other data communications devices usually have a system unit that processes radio frequency (RF) signals. This unit is usually called front end. Basically, a front end comprises radio frequency filters, intermediate frequency (IF) filters, multiplexers, demodulators, amplifiers and other circuits that could provide such functions as amplification, filtering, conversion and more. Referring to FIG. 1, the front end usually includes an analog front end 100 which is the analog portion of a circuit, which precedes analog-to-digital conversion. Thus, the analog front end 100 performs some analog signal preprocessing in unit 110 and some other functions as described above, and then outputs the analog signal to an analog-to-digital converter 130. The quantized, i.e. digitized, output signal of the analog-to-digital converter 130 is then supplied to a digital signal processor 140.

As can be seen from FIG. 1, the analog front end 100 of conventional data communications receivers may further have a unit 120 for downconverting the received (and preprocessed) analog signal. Conventionally, RF carriers conveying data by way of some modulation technique are downconverted from the high frequency carrier to some other intermediate frequency through a process called mixing. Following the mixing process, the baseband signal is recovered through some type of demodulation scheme.

Receiver architectures exist where unit 120 has zero-IF and/or low-IF topology. This will now be explained in more detail with reference to FIGS. 2 and 3.

FIG. 2 is a simplified diagram illustrating the zero-IF approach for integrated receivers. In the zero-IF approach, the incoming signal, which is at radio frequency, is converted by mixer 200 directly to baseband (BB). Such direct conversion architectures have simplified filter requirements and can be integrated in a standard silicon process, making this design potentially attractive for wireless applications. However, there may be problems with the DC offset, IQ mismatch and with low frequency noise.

FIG. 3 illustrates the low-IF approach. As can be seen, the low-IF architecture operates at an intermediate frequency close to the baseband (like the zero-IF approach) and can therefore be integrated like the zero-IF circuits. However, there is a second downconverter 330 to convert the intermediate frequency signals to baseband. Low-IF devices can avoid the problems of DC offset, IQ mismatch and low frequency noise but may require additional image rejection. For this reason, an image rejection unit 320 is added in the low-IF topology.

Thus, the zero-IF and low-IF approaches each have their own advantages and disadvantages. This is why conventional communications devices exist that use either the zero-IF approach or the low-IF approach in the analog front end. Further, dual-band RF transceivers for WLAN systems exist where a direct conversion technique is used for one WLAN mode, and a low-IF architecture is used for another WLAN mode.

### SUMMARY OF THE INVENTION

An improved multi-mode data communications technique is provided that may simplify manufacturing and improve efficiency.

According to one embodiment, a WLAN receiver is provided that is capable of receiving data signals that are modulated in accordance with an individual one of at least two different modulation schemes. The WLAN receiver comprises a front end section having an analog front end unit and a digital front end unit. The digital front end unit comprises a first signal processing branch for processing received data signals modulated in accordance with a first one of the at least two different modulation schemes, and a second signal processing branch for processing received data signals modulated in accordance with a second one of the at least two different modulation schemes. The first and second signal processing branches have low-IF topologies.

According to another embodiment, there is provided an integrated circuit chip that has circuitry for processing data signals modulated in accordance with an individual one of at least two different modulation schemes. This circuitry comprises a front end circuit that has an analog front end circuit and a digital front end circuit. The digital front end circuit comprises a first signal processing branch for processing received data signals modulated in accordance with a first one of the at least two different modulation schemes, and a second signal processing branch for processing received data signals modulated in accordance with a second one of the at least two different modulation schemes. The first and second signal processing branches have low-IF topologies.

In a further embodiment, a method of processing received data signals in a data communications device is provided where the data signals are modulated in accordance with either one of at least two different modulation schemes. The data communications device comprises a front end section that has an analog front end unit and a digital front end unit. The method comprises determining which one of the at least two different modulation schemes is applied to a received data signal. The method further comprises performing low-IF processing of the received data signal in a first signal processing branch of the digital front end unit if it is determined that a first one of the at least two different modulation schemes is applied, or in a second signal processing branch of the digital front end unit if it is determined that a second one of the at least two different modulated schemes is applied.

### BRIEF DESCRIPTION OF THE DRAWINGS

The accompanying drawings are incorporated into and form a part of the specification for the purpose of explaining the principles of the invention. The drawings are not to be construed as limiting the invention to only the illustrated and described examples of how the invention can be made and used. Further features and advantages will become apparent from the following and more particular description of the invention, as illustrated in the accompanying drawings, wherein:

FIG. 1 is a block diagram illustrating the front end of a conventional data communications receiver;

FIG. 2 is a simplified diagram illustrating the zero-IF approach;

FIG. 3 is a simplified diagram illustrating the low-IF approach;

FIG. 4 is a block diagram depicting components of a data communications device according to an embodiment;

FIG. 5 is a block diagram illustrating the components of a digital front end section of the device shown in FIG. 4; and

FIG. 6 is a flow chart illustrating a process of operating the data communications device shown in FIGS. 4 and 5, according to an embodiment.

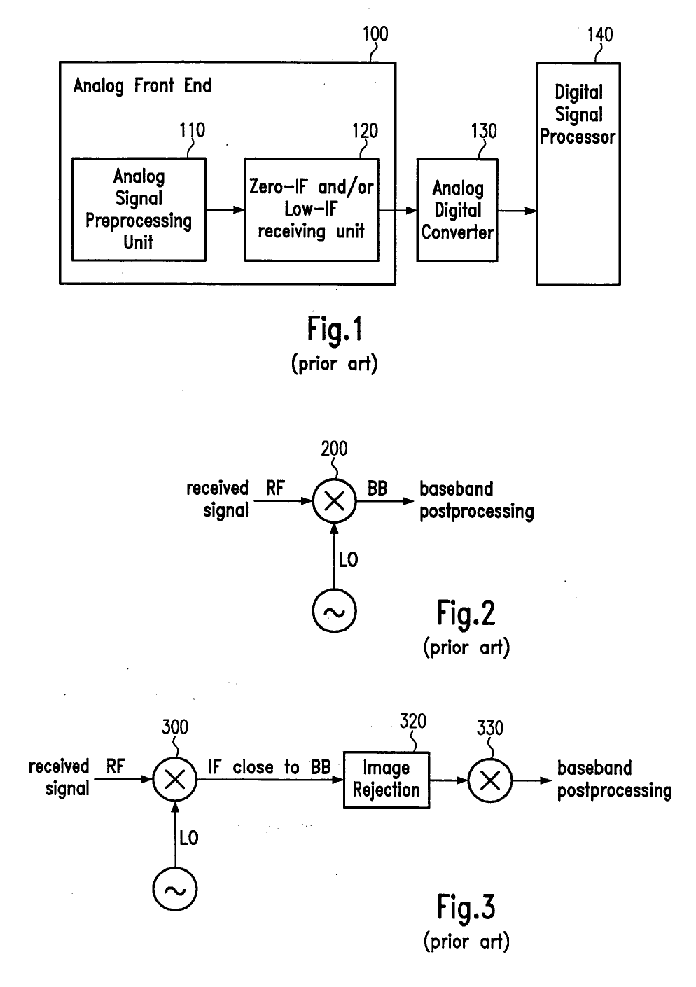

### DETAILED DESCRIPTION OF THE INVENTION

The illustrative embodiments of the present invention will be described with reference to the figure drawings wherein like elements and structures are indicated by like reference numbers.

As will be apparent from the more detailed description of the embodiments, a multi-mode data communications receiver technique is provided where the digital front end has two or more branches for different modulation schemes and each branch has low-IF topologies. It may be seen from the following description that the use of two (or more) low-IF branches in the digital receiver front end may simplify the manufacturing and improve the efficiency of the receiver architecture.

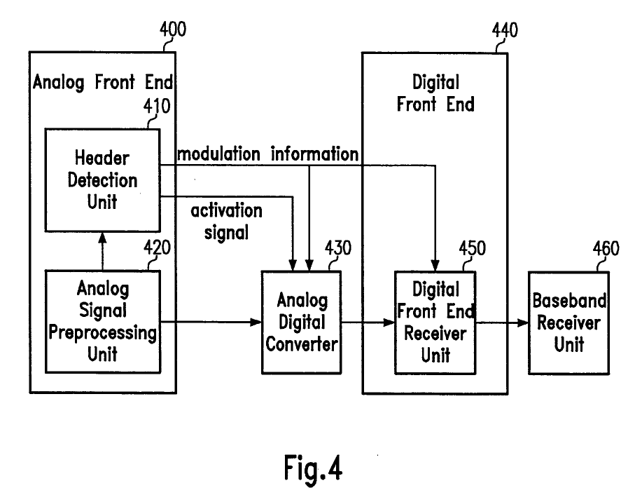

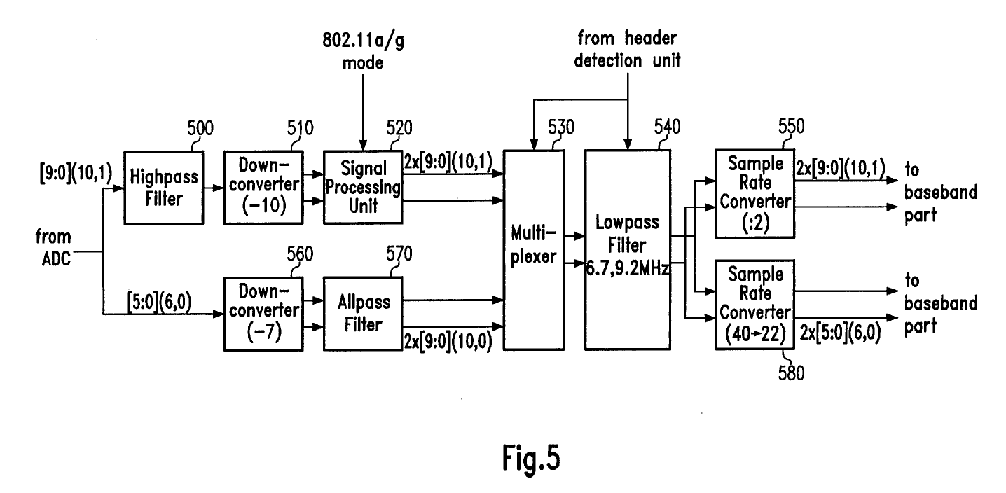

Referring first to FIG. 4, a block diagram is shown depicting the analog front end 400 and digital front end 440 of the data communications device (such as a WLAN receiver) according to an embodiment. The analog and digital front ends 400, 440 are interconnected by means of an analog-to-digital converter 430 that converts the analog output signal of the analog front end 400 to digital signals. In an embodiment, the analog output signal of the analog front end 400 may be preprocessed by an analog signal preprocessing unit 420 that may be part of the analog front end 400. The quantized digital signal that is output by the analog-to-digital converter 430 may be supplied to a digital front end receiver unit 450 of the digital front end 440 for further processing. The resulting baseband signal is then supplied to the baseband receiver unit 460 of the data communications device.

It is to be noted that the analog-to-digital converter 430 of the present embodiment may be part of the analog front end 400. In another embodiment, the analog-to-digital converter 430 may be located in the digital front end 440.

In the embodiments, the downconversion from radio frequency to the baseband is performed in the digital front end 440, and may be particularly performed in the digital front end receiver unit 450.

As can be seen from FIG. 4, the analog front end 400 further comprises a header detection unit 410 that detects a header in the incoming (and potentially preprocessed) signal, and that activates the analog-to-digital converter 430 if a header is detected. For this purpose, the header detection unit 410 of the analog front end 400 is connected to the analog-to-digital converter 430 to provide an activation signal upon detecting a header.

In one embodiment, the activation signal is set for each individual header and unset at the end of the payload. In another embodiment, the activation signal is set upon detecting a first header and unset at the end of the last payload in a sequence of data packets each having a header and a payload field.

The header detection unit 410 may further make a decision on the nature of the detected signal, based on the header properties. Particularly, the header detection unit 410 may extract modulation information and/or information with respect to a WLAN mode such as 802.11b, a or g, and supply this modulation information to the digital front end receiver unit 450 and to the analog-to-digital converter 430. As will be described in more detail below, the receiver unit 450 in the digital front end 440 and the analog-to-digital converter 430 may make use of this modulation information for proper operation of the low-IF branches.

In the present embodiment, one modulation scheme may be one complying with the IEEE 802.11b specification. In this mode, the signals may be Barker modulated or CCK modulated. Further, IEEE 802.11a/g modes may be used where an OFDM modulation scheme is applied.

Referring now to FIG. 5, the components of the digital front end receiver unit 450 of the digital front end 440 shown in FIG. 4 are depicted in more detail. As apparent from FIG. 5, the digital front end receiver unit 450 has two branches each having low-IF topology. In further embodiments, there may be more than just two branches.

In the first branch of FIG. 5, 802.11b compliant processing is performed. This branch comprises the downconverter 560, the allpass filter 570, the multiplexer 530, the lowpass filter 540, and the sample rate converter 580. In the second branch, 802.11a/g compliant OFDM signals are processed. This branch comprises the highpass filter 500, the downconverter 510, the signal processing unit 520, the multiplexer 530, the lowpass filter 540, and the sample rate converter 550.

Before discussing the various components in more detail, it is to be noted that the multiplexer 530 and the lowpass filter 540 are part of both branches. By having these units shared by both branches, circuit development and manufacturing costs are significantly reduced. It is to be noted that further components might also be designed in a shared fashion in further embodiments.

As can be seen from FIG. 5, the shared components 530, 540 receive the modulation information signal from the header detection unit 410. This signal allows the units to reconfigure their specific properties to properly fulfill the requirements of the respective modulation technique applied in each individual mode.

Discussing now the 802.11b branch, the quantized real output signal of the analog-to-digital converter 430 is first downconverted to near the baseband by the downconverter 560. In the 802.11b mode, the analog-to-digital converter 430 is controlled to have a quantization of 6 bits. The intermediate frequency is 7 MHz in the present embodiment. The downconverter 560 outputs the downconverted complex signal to the allpass filter 570.

The allpass filter 570 performs allpass filtering on the received complex IF signal for an equalization of phase non-linearities caused in the analog front end 400. In the present embodiment, the allpass filter 570 is an IIR (Infinite Impulse Response) filter.

As the complex baseband signal may still have unwanted images, it passes the lowpass filter 540 to suppress those images. The lowpass filter 540 has a cutoff frequency of about 6.7 MHz in the present embodiment, when being in an 802.11b mode. The cutoff frequency of the present embodiment is chosen to be sufficiently low to remove the unwanted images but slightly above the Nyquist frequency of 5.5 MHz in order to lower the effect of group delay distortions caused by the filter.

In the present embodiment, the lowpass filter 540 is an elliptic IIR lowpass filter.

The anti-image filtered signal is then supplied to the sample rate converter 580 that converts the sample rate to 22 MHz and finally passes the resulting signal to the 802.11b compliant baseband receiver part.

In the 802.11b branch, the quantization is 6 bits before the downconverter 560, and 10 bits after the downconverter 560 with a (10,0) fixed point interpretation. The latter refers to the range of the physical voltage value of the analog-to-digital converter input. The extension of the resolution from 6 to 10 bits by the downconverter 560 may compensate for any lack of power normalization in the digital front end 440.

Referring now to the 802.11a/g branch, the quantized real output signal of the analog-to-digital converter 430 is converted by the downconverter 510 to near the baseband. The quantization of the analog-to-digital converter 430 in the 802.11a/g OFDM mode is 10 bits. The quantized real output signal of the analog-to-digital converter 430 may first pass a highpass filter 500.

Subsequent to the downconverter 510, there may be some signal processing in unit 520 dependent on the exact WLAN mode. That is, the signal processing unit 520 may operate differently in the 802.11a mode and in the 802.11g mode. In the present embodiment, the information as to the mode is provided to the signal processing unit 520 by the header detection unit 410 of the analog front end 400.

Unwanted images are removed by passing through the lowpass filter 540 which may again be an elliptic IIR lowpass filter. The lowpass filter 540 has a cutoff frequency of about 9.2 MHz when operating in the 802.11a/g branch.

The image rejected signal output by the lowpass filter 540 is then supplied to the sample rate converter 550 where the sampling rate is reduced by the factor of 2. The resulting signal is then passed to the 802.11a/g compliant baseband receiver part of the data communications device.

The quantization in the OFDM branch is 10 bits with a (10,1) fixed point interpretation. Again, the latter refers to the range of the physical voltage value of the analog-to-digital converter input.

As described above, the filters used in the embodiments may be elliptic IIR filters. In further embodiments, the filters may be multiplierless filters as described in L. D. Milić, IEEE Transactions on Signal Processing, Vol. 47, No. 2, February 1999, pp. 469 to 479.

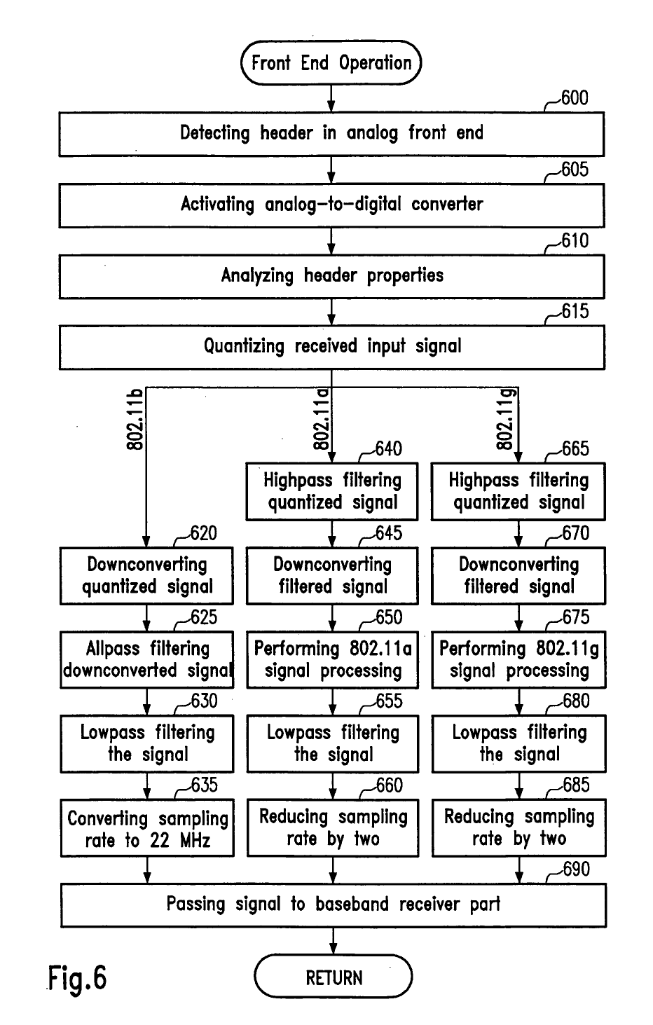

Referring now to FIG. 6, a flow chart is provided illustrating the process of performing multi-mode low-IF reception according to the embodiment. In step 600, a header is detected in the header detection unit 410 of the analog front end 400. The header detection unit 410 then generates an activation signal and submits same to the analog-to-digital converter 430 to activate this unit (step 605). Further, the header detection unit 410 analyzes header properties in step 610 to extract modulation information and provide this information to the digital front end 440, and to the analog-to-digital converter 430. In step 615, the received input signal is then digitized with a degree of quantization of either 10 bits or 6 bits dependent on the mode indicated by the extracted information.

If the received signal is modulated in compliance with the IEEE 802.11b specification, the quantized signal is downconverted in step 620, allpass filtered in step 625, lowpass filtered in step 630, and subjected to sample rate conversion in step 635. If in the 802.11a/g mode, there may be an initial highpass filtering of the quantized signal in steps 640, 665. The filtered signal is then downconverted in steps 645 or 670. Further, signal processing is performed either in step 650 or in step 675 dependent on the WLAN mode. Finally, the signal is lowpass filtered in steps 655, 680 and sample rate reduced by the factor of 2 in steps 660, 685. Finally, the produced baseband signal is passed to the baseband receiver part of the device.

While the invention has been described with respect to the physical embodiments constructed in accordance therewith, it will be apparent to those skilled in the art that various modifications, variations and improvements of the present invention may be made in the light of the above teachings and within the purview of the appended claims without departing from the spirit and intended scope of the invention. In addition, those areas in which it is believed that those of ordinary skill in the art are familiar, have not been described herein in order to not unnecessarily obscure the invention described herein. Accordingly, it is to be understood that the invention is not to be limited by the specific illustrative embodiments, but only by the scope of the appended claims.

What is claimed is:

1. A WLAN (Wireless Local Area Network) receiver capable of receiving data signals modulated in accordance with an individual one of at least two different modulation schemes, said WLAN receiver comprising a front end section having an analog front end unit and a digital front end unit, said digital front end unit comprising a first signal processing branch for processing received data signals modulated in accordance with a first one of said at least two different modulation schemes, and a second signal processing branch for processing received data signals modulated in accordance with a second one of said at least two different modulation schemes, said first and second signal processing branches having low-IF (Intermediate Frequency) topologies.

2. The WLAN receiver of claim 1, wherein said first signal processing branch and said second signal processing branch share at least one unit included in said low-IF topologies, said at least one unit being connected to receive a signal indicative of which one of said at least two different modulation schemes is currently applied to the received data signals.

3. The WLAN receiver of claim 2, wherein said at least one unit comprises a lowpass filter unit for image rejection.

4. The WLAN receiver of claim 3, wherein said lowpass filter unit comprises at least one digital IIR (Infinite Impulse Response) filter.

5. The WLAN receiver of claim 4, wherein said at least one digital IIR filter is an elliptic IIR filter.

6. The WLAN receiver of claim 3, wherein said lowpass filter unit has a cutoff frequency selectively chosen in dependence on the indicated modulation scheme.

7. The WLAN receiver of claim 3, wherein said at least one unit further comprises a multiplexer unit for selectively connecting said lowpass filter unit to units of said first or second signal processing branch in dependence on the received signal indicative of the modulation scheme.

8. The WLAN receiver of claim 2, further comprising a header detection unit adapted to analyze header information of received data signals and generate said signal indicative of which one of said at least two different modulation schemes is currently applied to the received data signals.

9. The WLAN receiver of claim 8, wherein said header detection unit is comprised in said analog front end unit.

10. The WLAN receiver of claim 8, further comprising an analog-to-digital converter unit connected to digitize an output of said analog front end unit to be provided to said digital front end unit, said analog-to-digital converter unit being capable of digitizing said output with different degrees of quantization, wherein said signal indicative of which one of said at least two different modulation schemes is currently applied to the received data signals is supplied to said analog-to-digital converter unit to control the degree of quantization dependent thereon.

11. The WLAN receiver of claim 8, further comprising an analog-to-digital converter unit connected to digitize an output of said analog front end unit to be provided to said digital front end unit, wherein said header detection unit is adapted to further generate an activation signal upon detection of a header, said activation signal being supplied to said analog-to-digital converter unit to activate this unit.

12. The WLAN receiver of claim 1, further comprising a header detection unit adapted to analyze header information of received data signals and generate a signal indicative of which one of said at least two different modulation schemes is currently applied to the received data signals, said signal being supplied to said digital front end unit to control operation of said first and second signal processing branches.

13. The WLAN receiver of claim 12, wherein said header detection unit is comprised in said analog front end unit.

14. The WLAN receiver of claim 12, further comprising an analog-to-digital converter unit connected to digitize an output of said analog front end unit to be provided to said digital front end unit, wherein said header detection unit is adapted to generate an activation signal upon detection of a header, said activation signal being supplied to said analog-to-digital converter unit to activate this unit.

15. The WLAN receiver of claim 1, wherein said first one of said at least two different modulation schemes is a CCK (Complementary Code Keying) modulation scheme.

16. The WLAN receiver of claim 1, wherein said first one of said at least two different modulation schemes is a Barker modulation scheme.

17. The WLAN receiver of claim 1, wherein said first signal processing branch is adapted to process received data signals modulated in accordance with the IEEE 802.11b specification.

18. The WLAN receiver of claim 1, wherein said second one of said at least two different modulation schemes is an OFDM (Orthogonal Frequency Division Multiplexing) modulation scheme.

19. The WLAN receiver of claim 1, wherein said second signal processing branch is adapted to process received data signals modulated in accordance with the IEEE 802.11a and/or IEEE 802.11g specifications.

20. The WLAN receiver of claim 1, wherein said first signal processing branch comprises a downconverter unit connected to receive a digitized real output signal of said analog front end unit and adapted to downconvert said signal to a complex signal at an intermediate frequency close to the baseband.

21. The WLAN receiver of claim 20, wherein said digitized real output signal of said analog front end unit is digitized with a first degree of quantization and said downconverter unit is adapted to output a downconverted digital signal with a second degree of quantization, said second degree of quantization being different from said first degree of quantization.

22. The WLAN receiver of claim 21, wherein said second degree of quantization is greater than said first degree of quantization.

23. The WLAN receiver of claim 21, wherein said second degree of quantization is equal to the degree of quantization of the digitized real output signal of said analog front end unit supplied to said second signal processing branch prior to any downconversion.

24. The WLAN receiver of claim 1, wherein said first signal processing branch comprises an allpass filter unit to account for equalization of phase non-linearities caused by said analog front end unit.

25. The WLAN receiver of claim 24, wherein said allpass filter unit comprises at least one digital IIR (Infinite Impulse Response) filter.

26. The WLAN receiver of claim 25, wherein said at least one digital IIR filter is an elliptic IIR filter.

27. The WLAN receiver of claim 1, wherein said first signal processing branch comprises a lowpass filter unit for image rejection.

28. The WLAN receiver of claim 27, wherein said lowpass filter unit comprises at least one digital IIR (Infinite Impulse Response) filter.

29. The WLAN receiver of claim 28, wherein said at least one digital IIR filter is an elliptic IIR filter.

30. The WLAN receiver of claim 29, wherein said elliptic IIR filter has a cutoff frequency slightly above the Nyquist frequency.

31. The WLAN receiver of claim 1, wherein said first signal processing branch comprises a sample rate converter adapted to convert the sample rate down to a rate suitable for processing the signal at the baseband frequency.

32. The WLAN receiver of claim 1, wherein said second signal processing branch comprises a highpass filter unit connected to receive a digitized real output signal of said analog front end unit and adapted to highpass filter said signal.

33. The WLAN receiver of claim 32, wherein said highpass filter unit comprises at least one digital IIR (Infinite Impulse Response) filter.

34. The WLAN receiver of claim 1, wherein said second signal processing branch comprises a downconverter unit connected to receive a digitized real representation of a received data signal and adapted to downconvert said signal to a complex signal at an intermediate frequency close to the baseband.

35. The WLAN receiver of claim 1, wherein said second signal processing branch comprises a signal processing unit connected to receive a signal indicative of one of at least two different WLAN modes applying said second one of said at least two different modulation schemes, and adapted to perform signal processing dependent thereon.

36. The WLAN receiver of claim 1, wherein said second signal processing branch comprises a lowpass filter unit for image rejection.

37. The WLAN receiver of claim 36, wherein said lowpass filter unit comprises at least one digital IIR (Infinite Impulse Response) filter.

38. The WLAN receiver of claim 37, wherein said at least one digital IIR filter is an elliptic IIR filter.

39. The WLAN receiver of claim 38, wherein said elliptic IIR filter has a cutoff frequency slightly above the Nyquist frequency.

40. The WLAN receiver of claim 1, wherein said second signal processing branch comprises a sample rate converter adapted to convert the sample rate down to a rate suitable for processing the signal at the baseband frequency.

41. An integrated circuit chip having circuitry for processing data signals modulated in accordance with an individual one of at least two different modulation schemes, said circuitry comprising a front end circuit having an analog front end circuit and a digital front end circuit, said digital front end circuit comprising a first signal processing branch for processing received data signals modulated in accordance with a first one of said at least two different modulation schemes, and a second signal processing branch for processing received data signals modulated in accordance with a second one of said at least two different modulation schemes, said first and second signal processing branches having low-IF (Intermediate Frequency) topologies.

42. A method of processing received data signals in a data communications device, said data signals being modulated in accordance with either one of at least two different modulation schemes, said data communications device comprising a front end section having an analog front end unit and a digital front end unit, said method comprising:
determining which one of said at least two different modulation schemes is applied to a received data signal; and
performing low-IF (Intermediate Frequency) processing of said received data signal in a first signal processing branch of said digital front end unit if it is determined that a first one of said at least two different modulation schemes is applied, or in a second signal processing branch of said digital front end unit if it is determined that a second one of said at least two different modulation schemes is applied.

43. The method of claim 42, wherein performing low-IF processing comprises:
operating at least one unit shared by said first signal processing branch and said second signal processing branch; and
providing to said at least one unit a signal indicative of which one of said at least two different modulation schemes is applied to the received data signal.

44. The method of claim 43, wherein operating said at least one unit comprises:
performing lowpass filtering for image rejection.

45. The method of claim 44, wherein lowpass filtering comprises:
operating at least one digital IIR (Infinite Impulse Response) filter.

46. The method of claim 45, wherein operating said at least one digital IIR filter comprises:
operating an elliptic IIR filter.

47. The method of claim 44, wherein lowpass filtering comprises:
applying a cutoff frequency selectively chosen in dependence on the indicated modulation scheme.

48. The method of claim 44, wherein operating said at least one unit further comprises:
selectively connecting a lowpass filter unit for performing said lowpss filtering to units of said first or second signal processing branch in dependence on the received signal indicative of the modulation scheme.

49. The method of claim 43, further comprising:
analyzing header information of said received data signal; and
generating said signal indicative of which one of said at least two different modulation schemes is applied to the received data signal.

50. The method of claim 49, wherein said header information is analyzed by a header detection unit comprised in said analog front end unit.

51. The method of claim 49, further comprising:
digitizing an output of said analog front end unit with one of plural different degrees of quantization; and
providing the digitized output to said digital front end unit,
wherein the degree of quantization is controlled dependent on said signal indicative of which one of said at least two different modulation schemes is applied to the received data signal.

52. The method of claim 49, further comprising:
digitizing an output of said analog front end unit; and
providing the digitized output to said digital front end unit,
wherein digitizing is activated by an activation signal generated upon detection of a header.

53. The method of claim 42, further comprising:
analyzing header information of said received data signal;
generating a signal indicative of which one of said at least two different modulation schemes is applied to the received data signal; and
supplying said signal to said digital front end unit to control operation of said first and second signal processing branches.

54. The method of claim 53, wherein said header information is analyzed by a header detection unit comprised in said analog front end unit.

55. The method of claim 53, further comprising:
digitizing an output of said analog front end unit; and
providing the digitized output to said digital front end unit,
wherein digitizing is activated by an activation signal generated upon detection of a header.

56. The method of claim 42, wherein said first one of said at least two different modulation schemes is a CCK (Complementary Code Keying) modulation scheme.

57. The method of claim 42, wherein said first one of said at least two different modulation schemes is a Barker modulation scheme.

58. The method of claim 42, wherein said first signal processing branch processes received data signals modulated in accordance with the IEEE 802.11b specification.

59. The method of claim 42, wherein said second one of said at least two different modulation schemes is an OFDM (Orthogonal Frequency Division Multiplexing) modulation scheme.

60. The method of claim 42, wherein said second signal processing branch processes received data signals modulated in accordance with the IEEE 802.11a and/or IEEE 802.11g specifications.

61. The method of claim 42, further comprising:
receiving a digitized real output signal of said analog front end unit in said first signal processing branch; and
downconverting said signal to a complex signal at an intermediate frequency close to the baseband.

62. The method of claim 61, wherein said digitized real output signal of said analog front end unit is digitized with a first degree of quantization and the method further comprises:
outputting a downconverted digital signal with a second degree of quantization, said second degree of quantization being different from said first degree of quantization.

63. The method of claim 62, wherein said second degree of quantization is greater than said first degree of quantization.

64. The method of claim 62, wherein said second degree of quantization is equal to the degree of quantization of the digitized real output signal of said analog front end unit supplied to said second signal processing branch prior to any downconversion.

65. The method of claim 42, further comprising:
performing allpass filtering in said first signal processing branch to account for equalization of phase non-linearities caused by said analog front end unit.

66. The method of claim 65, wherein allpass filtering comprises:
operating at least one digital IIR (Infinite Impulse Response) filter.

67. The method of claim 66, wherein operating said at least one digital IIR filter comprises:
operating an elliptic IIR filter.

68. The method of claim 42, further comprising:
performing lowpass filtering in said first signal processing branch for image rejection.

69. The method of claim 68, wherein lowpass filtering comprises:
operating at least one digital IIR (Infinite Impulse Response) filter.

70. The method of claim 69, wherein operating said at least one digital IIR filter comprises:
operating an elliptic IIR filter.

71. The method of claim 70, wherein operating said elliptic IIR filter comprises:
applying a cutoff frequency slightly above the Nyquist frequency.

72. The method of claim 42, further comprising:
converting the sample rate in said first signal processing branch down to a rate suitable for processing the signal at the baseband frequency.

73. The method of claim 42, further comprising:
receiving a digitized real output signal of said analog front end unit; and
performing highpass filtering of said signal in said second signal processing branch.

74. The method of claim 73, wherein highpass filtering comprises:
operating at least one digital IIR (Infinite Impulse Response) filter.

75. The method of claim 42, further comprising:
receiving a digitized real representation of said received data signal in said second signal processing branch; and
downconverting said signal to a complex signal at an intermediate frequency close to the baseband.

76. The method of claim 42, further comprising:
receiving in said second signal processing branch a signal indicative of one of at least two different WLAN modes applying said second one of said at least two different modulation schemes; and
performing signal processing in said second signal processing branch dependent on said signal.

77. The method of claim 42, further comprising:
performing lowpass filtering in said second signal processing branch for image rejection.

78. The method of claim 77, wherein lowpass filtering comprises:
operating at least one digital IIR (Infinite Impulse Response) filter.

79. The method of claim 78, wherein operating said at least one digital IIR filter comprises:
operating an elliptic IIR filter.

80. The method of claim 79, wherein operating said elliptic IIR filter comprises:
applying a cutoff frequency slightly above the Nyquist frequency.

81. The method of claim 42, further comprising:
converting the sample rate in said second signal processing branch down to a rate suitable for processing the signal at the baseband frequency.
